(19) United States
(12) Patent Application Publication
(10) Pub. No.: US 2011/0211336 A1
(43) Pub. Date: Sep. 1, 2011

(54) LIGHT EMITTING DEVICE, AND ILLUMINATION LIGHT SOURCE, DISPLAY UNIT AND ELECTRONIC APPARATUS INCLUDING THE LIGHT EMITTING DEVICE

(75) Inventor: Shozo OSHIO, Osaka (JP)

(73) Assignee: PANASONIC CORPORATION, Osaka (JP)

(21) Appl. No.: 13/033,225

(22) Filed: Feb. 23, 2011

(30) Foreign Application Priority Data
Feb. 26, 2010 (JP) 2010-042039

(51) Int. Cl. G02F 1/13357; H01L 33/44

(52) U.S. Cl. 362/97.1; 257/89; 257/E33.059

(57) ABSTRACT

A light emitting device includes: a first semiconductor light emitting element having a solid-state blue light emitting element that emits blue light with a light emission peak in a wavelength range from 420 nm to less than 480 nm, and a first red phosphor layer that covers the solid-state blue light emitting element and includes a first red phosphor that emits red light with a light emission peak in a wavelength range from 600 nm to less than 680 nm; and a second semiconductor light emitting element having a solid-state green light emitting element that emits green light with a light emission peak in a wavelength range from 500 nm to less than 550 nm, and a second red phosphor layer that covers the solid-state green light emitting element and includes a second red phosphor that emits red light with a light emission peak in a wavelength range from 600 nm to less than 680 nm.

### BACKGROUND OF THE INVENTION

1. Field of the Invention

The present invention relates to a light emitting device utilizing solid-state light emitting elements and phosphors. The present invention also relates to an illumination light source, such as a backlight, including the light emitting device, and further relates to a display unit including the backlight and to an electronic apparatus including the display unit.

2. Description of Related Art

Conventionally, a light emitting device including a solid-state light emitting element, such as a light emitting diode (hereinafter referred to as an LED), and a phosphor in combination has been used as a light emitting device (hereinafter referred to as a three-band white light emitting device) that emits three-band white light usable as illumination light or backlight for a display unit.

Such a light emitting device has a configuration in which the solid-state light emitting element is covered with a phosphor layer. The phosphor converts the wavelength of a part of the light emitted from the solid-state light emitting element. The light emitting device is designed so that each of the light components of red, green, and blue, which are primary colors of light, is emitted through the light emissions from the solid-state light emitting element and the phosphor by selecting appropriately the types of the solid-state light emitting element and the phosphor. Although LED light has strong directivity, the directivity can be reduced in the light emitting device by covering the LED with the phosphor layer.

As an example of the above-mentioned light emitting device, JP 2008-140704 A discloses an LED backlight including a white LED light source device that has: a bluish green LED lamp that emits bluish green light by using, in combination, a blue LED element and a green phosphor; and a purple LED lamp that emits purple light by using, in combination, a blue LED element and a red phosphor. In this LED backlight, white light having a spectrum distribution including wavelength components of the primary colors of light is produced by additive color mixing of the bluish green light emitted from the bluish green LED lamp with the purple light emitted from the purple LED lamp.

Moreover, three-band white light emitting devices as described in U.S. Pat. No. 6,686,691 and U.S. Pat. No. 6,649,946, for example, in which an LED emits blue light, and a green phosphor and a red phosphor emit green light and red light, respectively, have become mainstream today.

Due to the fact that these light emitting devices utilize, as an output light component of the bluish green light or the white light, the green light emitted from the green phosphor that can be excited by blue light (due to the fact that the green phosphor converts the wavelength of the blue light (about 2.7 eV) absorbed therein to the green light (about 2.4 eV) having energy close to that of the blue light), they have excellent energy conversion efficiencies but suffer the following problems.

(1) Since the photon conversion efficiency from the blue light irradiating the green phosphor to the green light is low, the use amount of the green phosphor increases, leading to high cost.
(2) Since, in general, the green phosphor has a sharp absorption property with respect to the wavelength of the blue light, the spectral distribution of the bluish green light tends to vary easily due to a slight property difference between the blue LED and the green phosphor.
(3) The green light having an emission spectrum with a wide half value width is used because the choice of the green phosphor is limited. Thus, the light component ratios of the bluish green and yellow in the output light increase and the color separation among red, green, and blue becomes ambiguous. This not only reduces the brightness of the light that has transmitted through an RGB color filter but also lowers the color purity of each of the RGB lights.

In contrast, a light emitting device including no green phosphor but including a red phosphor also is proposed. For example, JP 2007-158296 A discloses a white LED including a blue LED chip, a green LED chip, and a mold part for sealing the blue LED chip and the green LED chip, wherein the mold part includes a red phosphor. Specifically, the white LED has a configuration in which the blue LED chip and the green LED chip are mounted on a single mounting substrate, and a single phosphor layer including the red phosphor covers both of the blue LED chip and the green LED chip together (see a figure in JP 2007-158296 A).

However, the light emitting device disclosed in JP 2007-158296 A requires to control at the same time the outputs of blue, green, and red lights emitted from at least three kinds of substances including the material that the light emitting layer in a solid-state light emitting element is composed of. This power control was difficult to perform from the viewpoint of the structure of the light emitting device.

Thus, there has been a problem in that when a light emitting device with such a structure is applied to a liquid crystal display panel (hereinafter referred to as an LCD) as a backlight, for example, it tends to cause unevennesses of color and brightness on the panel. This not only increases the lot-to-lot variation of the panels but also lowers the product yield, leading to high cost.

### SUMMARY OF THE INVENTION

An object of the present invention is to provide a three-band white light emitting device in which the color tone of light is controlled easily using a red phosphor, a solid-state blue light emitting element, and a solid-state green light emitting element. Another object of the present invention is to provide an illumination light source, particularly a backlight, configured so that the unevennesses of color and brightness in the output light are suppressed. Still another object of the present invention is to provide: a display unit configured so that the unevennesses of color and brightness are suppressed, no lot-to-lot variation occurs during production, and the product yield is increased; and an electronic apparatus including the display unit.

The light emitting device according to the present invention that has solved the aforementioned problems includes:

a first semiconductor light emitting element having a solid-state blue light emitting element that emits blue light with a light emission peak in a wavelength range from 420 nm to less than 480 nm, and a first red phosphor layer that covers the solid-state blue light emitting element and includes a first red phosphor that emits red light with a light emission peak in a wavelength range from 600 nm to less than 680 nm; and

a second semiconductor light emitting element having a solid-state green light emitting element that emits green light with a light emission peak in a wavelength range from 500 nm to less than 550 nm, and a second red phosphor layer that covers the solid-state green light emitting element and includes a second red phosphor that emits red light with a light emission peak in a wavelength range from 600 nm to less than 680 nm.

The illumination light source according to the present invention includes the light emitting device. One preferable embodiment of the illumination light source is a backlight.

The display unit according to the present invention includes the backlight.

The electronic apparatus according to the present invention includes the display unit.

The present invention can provide a three-band white light emitting device in which the color tone is controlled easily. Moreover, the present invention can provide an illumination light source, particularly a backlight, configured so that the unevennesses of color and brightness in the output light are suppressed. Furthermore, the present invention can provide a display unit and an electronic apparatus configured so that the unevennesses of color and brightness are suppressed, no lot-to-lot variation occurs during production, and the product yield is increased.

### BRIEF DESCRIPTION OF THE DRAWINGS

FIG. 1 shows collectively a schematic cross-sectional view illustrating one example of the light emitting device according to the present invention and spectral distributions of its output lights.

FIG. 2 is a schematic cross-sectional view showing another example of the light emitting device according to the present invention.

FIG. 3 is a diagram showing one example of the spectral distribution of output light from the light emitting device according to the present invention.

FIG. 4 is a diagram showing one example of the spectral distribution of light emitted from a first semiconductor light emitting element included in the light emitting device according to the present invention.

FIG. 5 is a diagram showing one example of the spectral distribution of light emitted from a second semiconductor light emitting element included in the light emitting device according to the present invention.

FIG. 6 is a schematic cross-sectional view showing still another example of the light emitting device according to the present invention.

FIG. 7 is a schematic perspective view showing one example of the backlight according to the present invention.

### DETAILED DESCRIPTION OF THE INVENTION

Hereinafter, embodiments of the present invention will be described with reference to the drawings.

### Embodiment 1

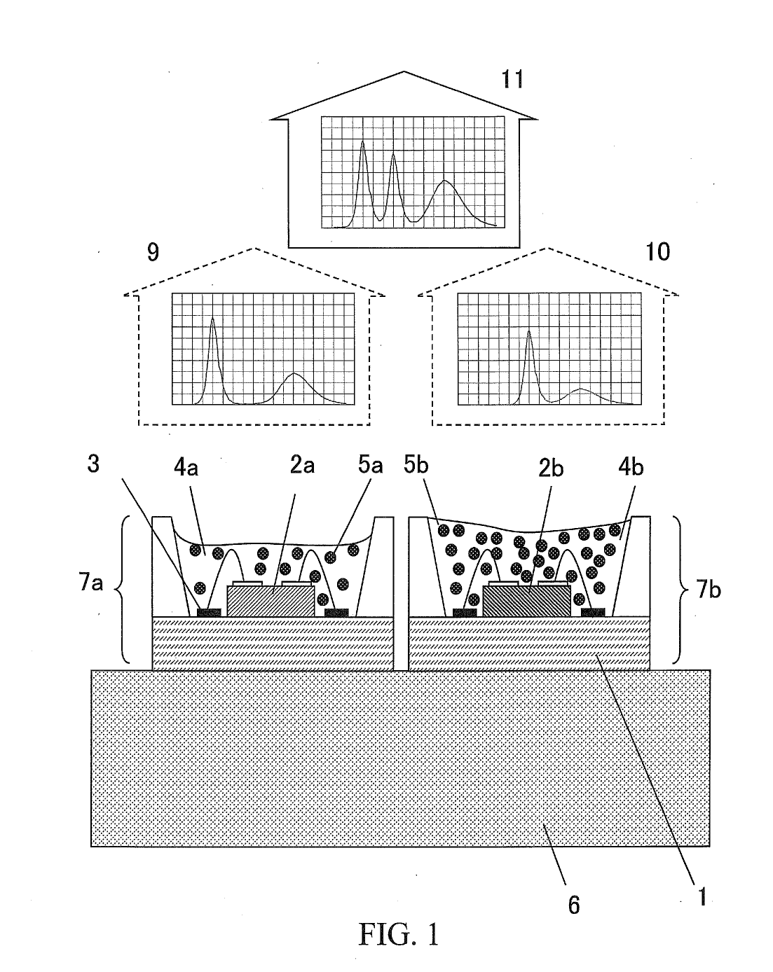

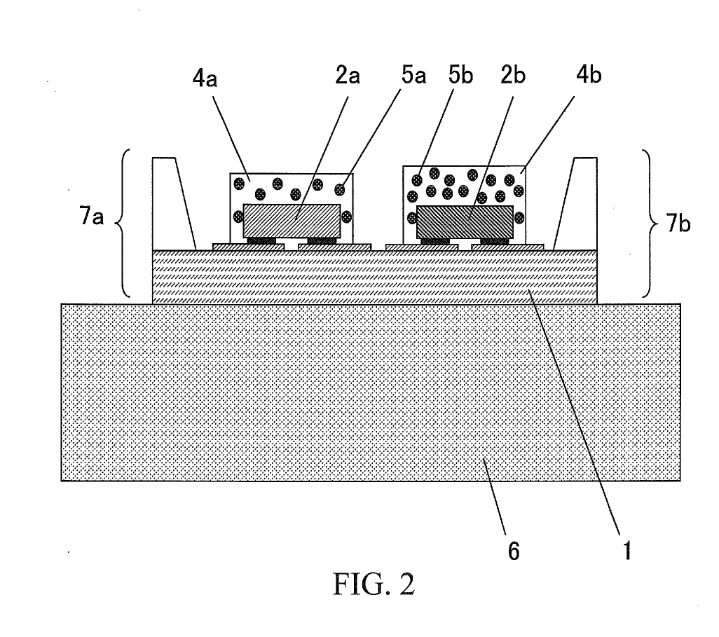

FIGS. 1 and 2 each are a diagram showing an example of Embodiment 1 that is a light emitting device according to the present invention.

The light emitting device of Embodiment 1 includes: a first semiconductor light emitting element 7a having a solid-state blue light emitting element 2a that emits blue light with a light emission peak in a wavelength range from 420 nm to less than 480 nm, and a first red phosphor layer 4a that covers the solid-state blue light emitting element 2a and includes a first red phosphor 5a that emits red light with a light emission peak in a wavelength range from 600 nm to less than 680 nm; and a second semiconductor light emitting element 7b having a solid-state green light emitting element 2b that emits green light with a light emission peak in a wavelength range from 500 nm to less than 550 nm, and a second red phosphor layer 4b that covers the solid-state green light emitting element 2b and includes a second red phosphor 5b that emits red light with a light emission peak in a wavelength range from 600 nm to less than 680 nm.

In FIG. 1, a substrate 1 is a base on which each solid-state light emitting element is mounted. The solid-state blue light emitting element 2a is mounted on the left one of a pair of the substrates 1. The solid-state blue light emitting element 2a is covered with the first phosphor layer 4a. The phosphor layer 4a includes the first red phosphor 5a and is formed of, for example, a mixture containing at least a light-transmissive resin (not shown) and the red phosphor 5a. A patterning wiring 3 is an electrode for supplying electric power to each solid-state light emitting element. The patterning wiring 3 and the solid-state blue light emitting element 2a are connected electrically to each other with a wire. In this way, the first semiconductor light emitting element 7a is fabricated.

In contrast, the solid-state green light emitting element 2b is mounted on the right one of the pair of the substrates 1. The solid-state green light emitting element 2b is covered with the second phosphor layer 4b. The phosphor layer 4b is formed of, for example, a mixture containing at least a light-transmissive resin (not shown) and the second red phosphor 5b. The patterning wiring 3 and the solid-state green light emitting element 2b are connected electrically to each other with a wire. In this way, the second semiconductor light emitting element 7b is fabricated.

The first semiconductor light emitting element 7a and the second semiconductor light emitting element 7b are mounted on a substrate 6 to fabricate the light emitting device.

FIG. 2 shows another example of Embodiment 1, which is different from the light emitting device shown in FIG. 1 in that the solid-state blue light emitting element 2a and the solid-state green light emitting element 2b are placed on the same single substrate 1 and mounted directly on the patterning wirings 3 so as to be supplied with the electric power.

In the above-mentioned light emitting devices, the first semiconductor light emitting element 7a emits blue/red mixed color light (purplish mixed color light) 9 obtained by allowing the first red phosphor 5a to convert a wavelength of at least a part of the blue light emitted from the solid-state blue light emitting element 2a, and the second semiconductor light emitting element 7b emits green/red mixed color light (yellowish mixed color light) 10 obtained by allowing the second red phosphor 5b to convert a wavelength of at least a part of the green light emitted from the solid-state green light emitting element 2b. The emitted blue/red mixed color light (purplish mixed color light) 9 and green/red mixed color light (yellowish mixed color light) 10 are mixed with each other further to obtain white light 11.

In Embodiment 1, as described above, the solid-state blue light emitting element 2a and the solid-state green light emitting element 2b are covered with the independent red phosphor layers, respectively, so as to form a pair of the semiconductor light emitting elements independent from each other.

Generally, it is known that the light emitted from an LED has strong directivity. However, in the above-mentioned configuration, even if the lights emitted from the solid-state blue light emitting element 2a and the solid-state green light emitting element 2b have strong directivities, the directivities of the primary lights (blue light and green light) emitted from these solid-state light emitting elements are suppressed because the red phosphors 5a, 5b function as light diffusers. Accordingly, a phenomenon of color separation (a phenomenon caused by the strong directivity of the LED light) between the LED light and the light whose wavelength has been converted by the phosphor is alleviated, so that uniform illumination light in which the unevennesses of color tone and brightness are suppressed is emitted. Therefore, in the light emitting device according to the present invention, it is preferable that the red phosphor layer 4a is disposed so as to cover at least a main light extraction surface of the solid-state blue light emitting element 7a, and the red phosphor layer 4b is disposed so as to cover at least a main light extraction surface of the solid-state green light emitting element 7b.

Conventional light emitting devices have a configuration in which a single red phosphor layer covers a solid-state blue light emitting element and a solid-state green light emitting element, requiring control at the same time of the outputs of blue, green, and red lights emitted from at least three kinds of substances. However, in the light emitting device of Embodiment 1, since the solid-state blue light emitting element and the solid-state green light emitting element have the red phosphor layers, respectively, to fabricate a pair of the independent semiconductor light emitting elements, it is only necessary to control at least two kinds of lights, that is, the purplish mixed color light 9 emitted from the first semiconductor light emitting element 7a and the yellowish mixed color light 10 emitted from the second semiconductor light emitting element 7b. The purplish mixed color light 9 and the yellowish mixed color light 10 can be controlled independently, and the red phosphors absorb only one of the blue light and the green light. This makes it easy to stabilize the color tones and light emission intensities of the purplish mixed color light 9 and the yellowish mixed color light 10, thereby making it extremely easy to control the color tone of the output light. Particularly, since the red phosphor layer in the first semiconductor light emitting element 7a and that in the second semiconductor light emitting element 7b can be designed separately, the color tone of the output light from the three-band white light emitting device can be controlled with only repeated control of the blue light and the green light.

Furthermore, when the first semiconductor light emitting element 7a or the second semiconductor light emitting element 7b is found to emit light with an undesired color tone unexpectedly, it is possible at this point in time to remove them from the production process as defective parts without assembling the final light emitting device. As a result, it also is possible to reduce the production loss.

Moreover, in Embodiment 1, solid-state light emitting elements (LEDs, for example) are used as light sources for the blue light and the green light. Thus, the above-mentioned disadvantages in using the green phosphor do not exist. In addition, since one of the red phosphors is excited by the green light having a light energy with a relatively small difference from that of the red light, the loss of the light energy is relatively small. Furthermore, since the solid-state light emitting elements each emit light having a spectrum with a narrow half value width, the ratios of the light emission components of bluish green and yellow are low, and the color separation among RGB is satisfactory in the resulting output light. Thus, in the case where the light emitting device of Embodiment 1 is used in a display unit, the color purities of RGB are satisfactory, and wide color gamut display as well as high brightness and high contrast image display are possible. Therefore, in one preferable embodiment of the light emitting device according to the present invention, none of a solid-state light emitting element and a phosphor substance that emit light with a light emission peak in a wavelength range from 480 nm to less than 500 nm, and a solid-state light emitting element and a phosphor substance that emit light with a light emission peak in a wavelength range from 550 nm to less than 600 nm is present.

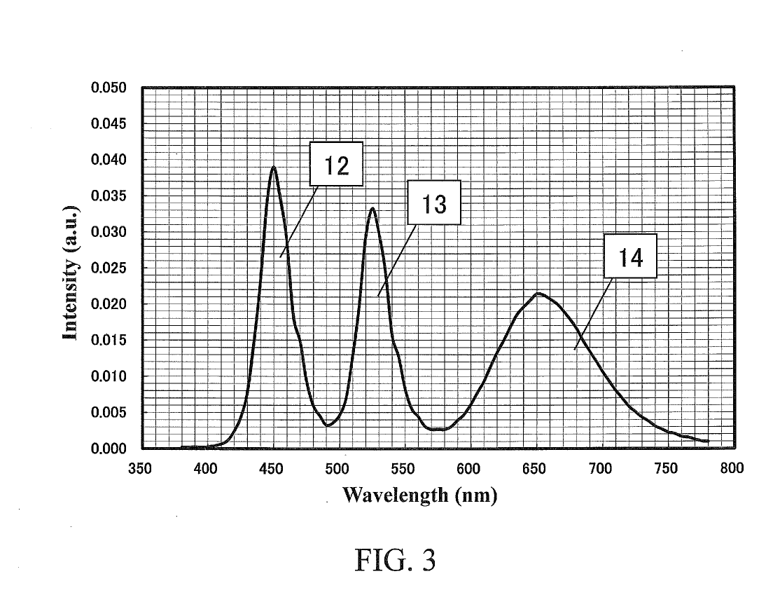

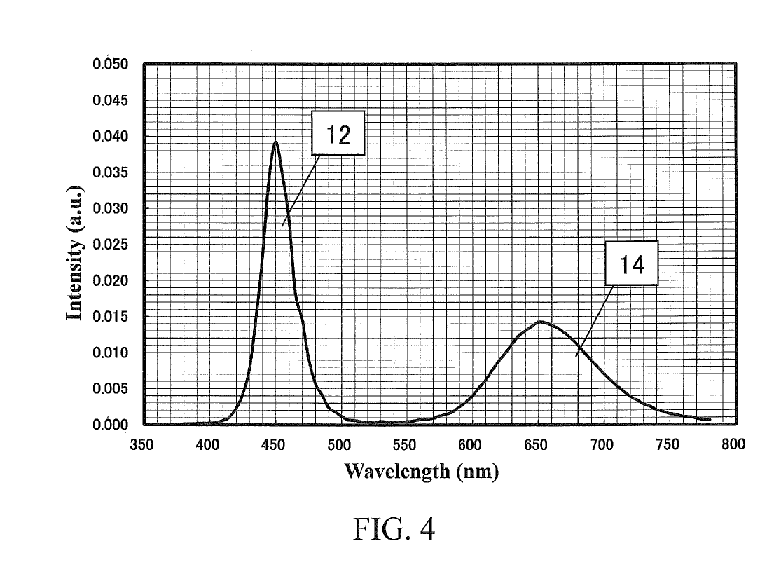

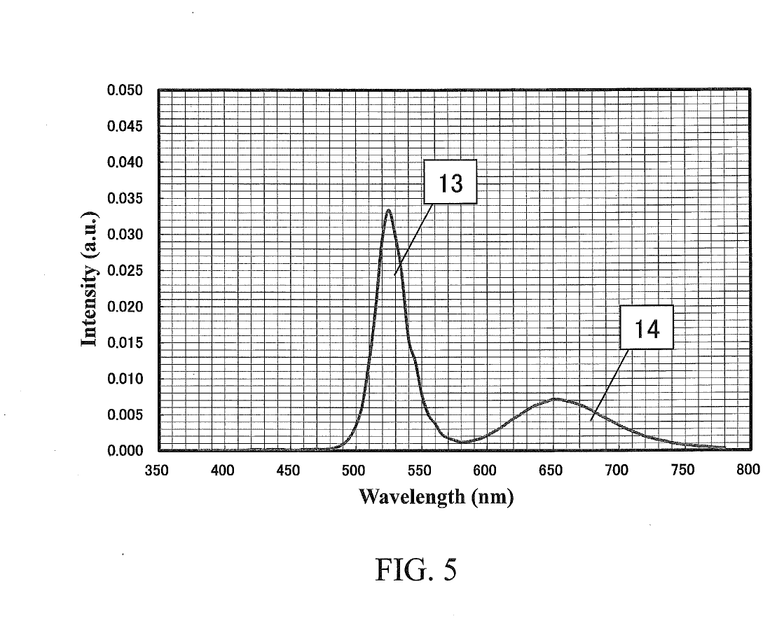

For reference, FIG. 3 shows an example of the spectral distribution of output light 11 emitted from the light emitting device according to the present invention, FIG. 4 shows an example of the spectral distribution of the blue/red mixed color light 9 emitted from the first semiconductor light emitting element 7a, and FIG. 5 shows an example of the spectral distribution of the green/red mixed color light 10 emitted from the second semiconductor light emitting element 7b.

As shown in FIG. 3, in the spectral distribution of the white output light 11 emitted from the light emitting device according to the present invention, at least the output intensity ratio of bluish green light at 490 nm and the output intensity ratio of the yellow light at 575 nm each are 20% or less, 10% or less in a more preferable embodiment, of the spectrum peak of the output light 11 because the green light emitted from the green LED, which has an emission spectrum with a narrow half value width, is utilized.

In this way, the color separation among RGB can be made clear, and the color purities of a blue light component 12, a green light component 13, a red light component 14 can be increased. Thereby, a high brightness and wide color gamut display can be realized.

In one preferable embodiment of the light emitting device according to the present invention, the first semiconductor light emitting element and the second semiconductor light emitting element are disposed so as to be spaced apart from each other.

Here, since white light is obtained by using, in combination, more than one kind of semiconductor light emitting elements that emit non-white lights, a planar white light source and a linear white light source can be configured in which more semiconductor light emitting elements can be mounted per unit area than in the case where a plurality of white semiconductor light emitting elements of one kind are used. As a result, the semiconductor light emitting elements can be disposed dispersedly, and white light with reduced unevennesses of brightness and color tone can be obtained. Moreover, it is possible to suppress mutual interference between the first semiconductor light emitting element and the second semiconductor light emitting element such that the blue light emitted from the first semiconductor light emitting element excites the red phosphor in the second semiconductor light emitting element to emit light. Thus, it is possible to suppress the color tone deviation of the white light that can be caused by this mutual interference. Furthermore, the production loss can be reduced because it is easy to configure the semiconductor light emitting elements in such a manner that when one of them is found to emit light with an undesired color tone, it easily can be replaced as a defective part with a good one.

Preferably, the blue light emitted from the solid-state blue light emitting element 2a has a light emission peak in a wavelength range from 440 nm to less than 470 nm. Preferably, the red light emitted from the first red phosphor layer 4a has a light emission peak in a wavelength range from 620 nm to less than 660 nm. Preferably, the green light emitted from the solid-state green light emitting element 2b has a light emission peak in a wavelength range from 510 nm to less than 535 nm. Preferably, the red light emitted from the second red phosphor layer 4b has a light emission peak in a wavelength range from 620 nm to less than 660 nm.

In the light emitting device according to the present invention, selecting the type of emission species makes it easy for all of the blue light, green light, and red light forming the output light to have a 1/10 persistence time of less than 3 msec, particularly less than 1 msec. Therefore, it is easy to design the light emitting device of the present invention so as to emit output light having a short persistence that is advantageous for image-adaptive light control and three-dimensional image display on LCDs.

Preferably, the red phosphor 5a and the red phosphor 5b each are at least one selected from the group consisting of an alkaline earth metal nitride phosphor activated with Eu²⁺ and an alkaline earth metal oxynitride phosphor activated with Eu²⁺. These phosphors not only are chemically stable but also have excellent heat resistance and less temperature quenching.

Moreover, it is known that these phosphors convert the wavelength of blue-to-green light so as to turn it to a red light by being excited by light with a wide wavelength range from blue to green at a high photon conversion efficiency (about 90%) that is close to the theoretical limit. It also is known that these phosphors emit red light with a super-short persistence, that is, a 1/10 persistence time of less than 1 msec.

Furthermore, in the excitation spectrum of the above-mentioned red phosphor activated with Eu²⁺ in a green range (510 to 535 nm), the decrease of the excitation intensity associated with an increase of the excitation wavelength is less and the slope of the excitation spectrum in the excitation wavelength range is gentler than in the excitation spectrum, in a blue range (440 to 470 nm), of a highly efficient green phosphor (usually, a green phosphor activated with Eu²⁺) that can be excited by blue light and has an emission spectrum with a relatively narrow half value width. Thus, the variation in the spectral distribution of the green/red mixed color light 10 (see FIG. 5) caused by a slight property difference between the green LED and the red phosphor, for example, is more suppressed than, for example, the variation in the spectral distribution of the blue/green mixed color light emitted from a conventional light emitting device as disclosed in JP 2008-140704 A (a light emitting device configured to emit blue/green mixed color light by using a blue LED and a green phosphor in combination).

Thereby, red light that is excellent from all the viewpoints of achieving long-term reliability, increasing the output, and shortening the persistence is emitted, and also, the light emitting device has less variation in the light emitting property and is suitable for industrial production.

Specific examples of the red phosphor activated with Eu²⁺ include: phosphors represented by (A) to (C) below; and phosphors having crystal lattices of these phosphors as the basic skeletons, with (SiN)⁺ therein having been partly substituted by (AlO)⁺. At least one red phosphor selected from these phosphors may be utilized appropriately. M in the following chemical formulae indicates an alkaline earth metal.

M₂Si₅N₈:Eu²⁺ (A)

MAlSiN₃:Eu²⁺ (B)

MAlSi₄N₇:Eu²⁺ (C)

The types of the red phosphors 5a and 5b may be the same as or different from each other, but it is preferable when they are of the same type from the viewpoint of production.

In the light emitting device according to the present invention, the pair of the semiconductor light emitting elements have the independent red phosphor layers, respectively. Thus, thicknesses of the phosphor layers and/or concentrations of the red phosphors included in the phosphor layers may be different between the first semiconductor light emitting element 7a and the second semiconductor light emitting element 7b. Also, by adjusting the thicknesses of the first red phosphor layer 4a and the second red phosphor layer 4b and/or the concentrations of the red phosphors, it is possible to obtain the desired purplish mixed color light 9 and the desired yellowish mixed color light 10 necessary to obtain the desired white output light 11 without changing the driving conditions for the first semiconductor light emitting element 7a and the second semiconductor light emitting element 7b. Accordingly, various devices including the light emitting device according to the present invention have less need to control the color tone of the output light by controlling a drive circuit, and thereby it is possible to drive them with a simple circuit configuration.

In the above-mentioned examples, each red phosphor layer is a resin phosphor layer obtained by dispersing phosphor powder in a light-transmissive resin, but it is not limited to such a phosphor layer. Each red phosphor layer may be, for example: an inorganic phosphor layer having a configuration in which a particulate phosphor is contained in a light-transmissive inorganic substance (such as glass); and a so-called light-transmissive fluorescent ceramic layer.

Preferably, in the light emitting device according to the present invention, the solid-state blue light emitting element 2a and the solid-state green light emitting element 2b each are an injection type electroluminescent element in which a light emitting layer is composed of an inorganic material. Thereby, the solid-state blue light emitting element 2a and the solid-state green light emitting element 2b have excellent long term reliability and an increased light output. Preferably, the light emitting layer of the solid-state blue light emitting element 2a is composed of the same type of material as that of the light emitting layer of the solid-state green light emitting element 2b. In this case, the solid-state blue light emitting element 2a and the solid-state green light emitting element 2b have similar light outputting properties to each other with respect to the input current when an electric power is supplied, reducing their color tone deviation caused by an increase in the supplied power. Moreover, it is less required to give special technical consideration to the drive circuit, reducing a burden on the circuit. Thereby, it is possible to drive the light emitting device with a simple drive circuit, making the light emitting device suitable for industrial production.

Specific examples of the inorganic material that the light emitting layer is composed of include group III-V semiconductor compounds such as GaP, InGaN, GaInN, and GaN. Among these, an InGaN semiconductor compound is preferable. It is known that a solid-state light emitting element in which a light emitting layer is composed of an InGaN semiconductor compound exhibits direct-transition-type light emission, and has a short persistence as well as excellent light emission efficiency. Thereby, the output can be increased.

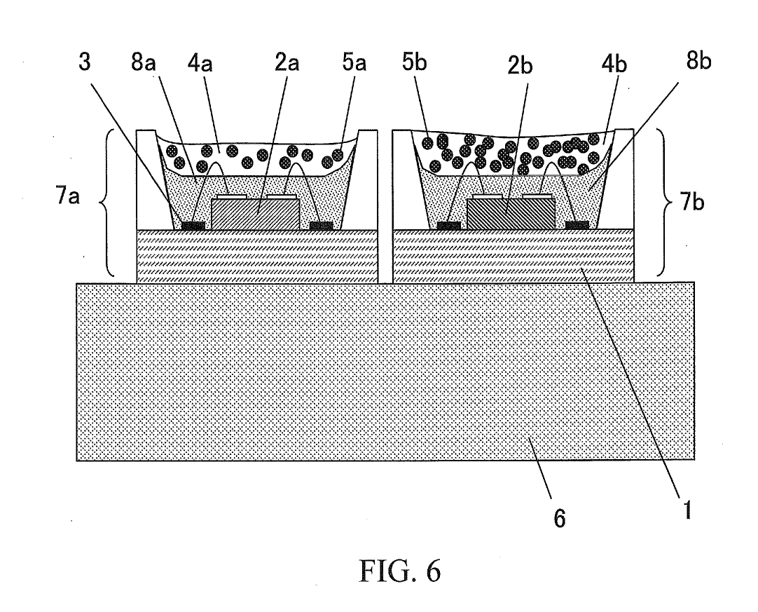

FIG. 6 shows another example of Embodiment 1. In this example, the first semiconductor light emitting element 7a further has a light diffuser 8a between the solid-state blue light emitting element 2a and the first red phosphor layer 4a, and the second semiconductor light emitting element 7b further has a light diffuser 8b between the solid-state green light emitting element 2b and the second red phosphor layer 4b.

The light diffusers 8a, 8b diffuse the primary lights (blue light and green light) emitted from the solid-state light emitting elements 2a, 2b, respectively. The red phosphor layers 4a, 4b further diffuse these diffused lights, and thereby the directivities of the primary lights are suppressed further and the color separation phenomenon can be alleviated further.

Examples of the light diffusers 8a, 8b include: a material obtained by dispersing inorganic powder particles (such as alumina particles and silica particles) in a light-transmissive resin; and a light-transmissive substrate with minute projections and depressions formed on at least one surface thereof so as to be like a frosted glass.

Contrary to the above-mentioned configuration, the light emitting device according to the present invention may have, although not shown, a configuration in which at least one of the purplish mixed color light and the yellowish mixed color light is output after having passed through the light diffuser, or a configuration in which the mixed color light (white light) composed of the purplish mixed color light and the yellowish mixed color light is output after having passed through the light diffuser. This also suppresses the color separation phenomenon in the same manner as described above.

The light emitting device according to the present invention can be produced in accordance with a publicly known method.

As described above, in the light emitting device according to the present invention, it is extremely easy to control the color tone of light. Therefore, the property variation during operation as well as the lot-to-lot property variation are suppressed. Moreover, the unevennesses of color and brightness in the output light also are reduced. In addition, the color separation among RGB also is satisfactory.

Thus, the light emitting device according to the present invention can be used suitably in light sources for common illumination apparatuses, light sources for image display units, etc.

Furthermore, when a display unit is fabricated using the light emitting device according to the present invention as a backlight, the color purities of RGB in the output light are satisfactory and the brightness is high, and also a wide color gamut display is possible. Moreover, no lot-to-lot variation occurs during production and the product yield is increased. Furthermore, for the sake of image-adaptive light control, the light emitting device is configured so that not only the amount of light as white light including all of the light components of red, green, and blue is controlled but also the light components of blue and red and the light components of green and red can be controlled independently. Therefore, more vivid and higher contrast images can be obtained.

### Embodiment 2

Next, an embodiment of the illumination light source according to the present invention will be described.

By using the light emitting device of Embodiment 1, it is possible to fabricate an illumination light source, such as a light source for an illumination apparatus including an illumination lamp and a thin illumination apparatus, and a light source (backlight) for an image display unit, in accordance with a publicly known method.

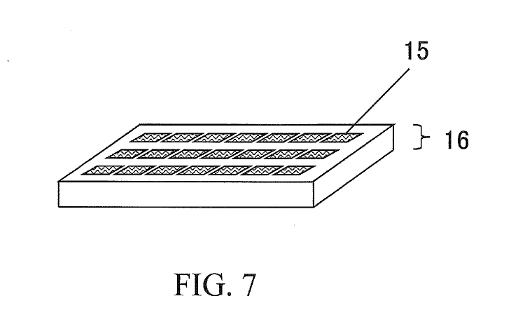

FIG. 7 is a schematic perspective view showing an example of a backlight as one specific example of the illumination light source according to the present invention. In a backlight 16, a plurality of the light emitting devices of Embodiment 1 are disposed dispersedly. The backlight 16 utilizes, as light emitted from a light emitting part 15, the output light 11 emitted from the light emitting device of Embodiment 1, or the purplish mixed color light 9 emitted from the first semiconductor light emitting element 7a and the yellowish mixed color light 10 emitted from the second semiconductor light emitting element 7b. It is possible to provide the backlight 16 with, for example, a lighting circuit system so as to emit white light suitable for wide color gamut display applications.

In the illumination light source according to the present invention, the unevennesses of color and brightness in the output light are suppressed.

### Embodiment 3

Next, an embodiment of the display unit according to the present invention will be described.

The display unit of Embodiment 3 includes the backlight of Embodiment 2 and can be fabricated using the backlight of embodiment 2 in accordance with a publicly known method. A typical example of the display unit is an LCD (liquid crystal display panel), which can be fabricated using at least the backlight of Embodiment 2, a light modulation element, and a color filter in combination.

The display unit according to the present invention is configured so that the unevennesses of color and brightness are suppressed, no lot-to-lot variation occurs during production, and the product yield is increased. Moreover, the color purities of RGB in the output light are satisfactory, the wide color gamut display is possible, and high contrast and high brightness images can be displayed.

### Embodiment 4

Next, the electronic apparatus according to the present invention will be described.

The electronic apparatus of Embodiment 4 includes the display unit of Embodiment 3 and can be fabricated using the display unit of Embodiment 3 in accordance with a publicly known method. Examples of the electronic apparatus include a liquid crystal display television, a mobile phone, a portable video camera, and a compact game machine. The liquid crystal display television can be fabricated, for example, using at least the display unit of Embodiment 3, a broadcasting receiver, and a sound system in combination.

The electronic apparatus according to the present invention is configured so that the unevennesses of color and brightness are suppressed, the color purities of RGB in the output light are satisfactory, wide color gamut display is possible, and high contrast and high brightness images can be displayed. Furthermore, the electronic apparatus has excellent visibility also in the outdoors under strong daylight, and thus is suitable for outdoor use.

The light emitting device according to the present invention can be used suitably in light sources for common illumination apparatuses, light sources for image display units, etc. Also, a display unit can be fabricated using the light emitting device according to the present invention as a backlight. Furthermore, an electronic apparatus (such as a liquid crystal display television, a mobile phone, a portable video camera, and a compact game machine) including the display unit can be fabricated.

The invention may be embodied in other forms without departing from the spirit or essential characteristics thereof. The embodiments disclosed in this specification are to be considered in all respects as illustrative and not limiting. The scope of the invention is indicated by the appended claims rather than by the foregoing description, and all changes which come within the meaning and range of equivalency of the claims are intended to be embraced therein.

1. A light emitting device comprising:
a first semiconductor light emitting element having a solid-state blue light emitting element that emits blue light with a light emission peak in a wavelength range from 420 nm to less than 480 nm, and a first red phosphor layer that covers the solid-state blue light emitting element and includes a first red phosphor that emits red light with a light emission peak in a wavelength range from 600 nm to less than 680 nm; and
a second semiconductor light emitting element having a solid-state green light emitting element that emits green light with a light emission peak in a wavelength range from 500 nm to less than 550 nm, and a second red phosphor layer that covers the solid-state green light emitting element and includes a second red phosphor that emits red light with a light emission peak in a wavelength range from 600 nm to less than 680 nm.

2. The light emitting device according to claim 1, wherein the first semiconductor light emitting element emits blue/red mixed color light obtained by allowing the first red phosphor to convert a wavelength of at least a part of the blue light emitted from the solid-state blue light emitting element, and the second semiconductor light emitting element emits green/red mixed color light obtained by allowing the second red phosphor to convert a wavelength of at least a part of the green light emitted from the solid-state green light emitting element.

3. The light emitting device according to claim 2, wherein the blue/red mixed color light and the green/red mixed color light are mixed with each other further.

4. The light emitting device according to claim 1, wherein the first red phosphor layer is disposed so as to cover at least a main light extraction surface of the solid-state blue light emitting element, and the second red phosphor layer is disposed so as to cover at least a main light extraction surface of the solid-state green light emitting element.

5. The light emitting device according to claim 1, wherein the first semiconductor light emitting element and the second semiconductor light emitting element are disposed so as to be spaced apart from each other.

6. The light emitting device according to claim 1, wherein the first and second red phosphors each are at least one selected from the group consisting of an alkaline earth metal nitride phosphor activated with Eu²⁺ and an alkaline earth metal oxynitride phosphor activated with Eu²⁺.

7. The light emitting device according to claim 1, wherein none of a solid-state light emitting element and a phosphor substance that emit light with a light emission peak in a wavelength range from 480 nm to less than 500 nm, and a solid light emitting element and a phosphor substance that emit light with a light emission peak in a wavelength range from 550 nm to less than 600 nm is present.

8. The light emitting device according to claim 1, wherein the solid-state blue light emitting element and the solid-state green light emitting element each are an injection type electroluminescent element in which a light emitting layer is composed of an inorganic material.

9. The light emitting device according to claim 8, wherein the inorganic material is an InGaN semiconductor compound.

10. The light emitting device according to claim 1, wherein thicknesses of the phosphor layers and/or concentrations of the red phosphors included in the phosphor layers are different between the first semiconductor light emitting element and the second semiconductor light emitting element.

11. The light emitting device according to claim 1, wherein the first semiconductor light emitting element further has a light diffuser between the solid-state blue light emitting element and the first red phosphor layer, and the second semiconductor light emitting element further has a light diffuser between the solid-state green light emitting element and the second red phosphor layer.

12. An illumination light source comprising the light emitting device according to claim 1.

13. The illumination light source according to claim 12 in the form of a backlight.

14. The illumination light source according to claim 13, wherein a plurality of the light emitting devices are disposed dispersedly so as to configure the backlight.

15. A display unit comprising the backlight according to claim 13.

16. An electronic apparatus comprising the display unit according to claim 15.
